(19) United States
(12) Patent Application Publication
(10) Pub. No.: US 2025/0357117 A1
(43) Pub. Date: Nov. 20, 2025

(54) DOPED TUNGSTEN CARBIDE LOW-K ETCH HARD MASK

(71) Applicant: Applied Materials, Inc., Santa Clara, CA (US)

(72) Inventors: Aykut AYDIN, Sunnyvale, CA (US); Rui CHENG, Santa Clara, CA (US); Guangyan ZHONG, Sunnyvale, CA (US); Xinhai HAN, Santa Clara, CA (US); Karthik JANAKIRAMAN, San Jose, CA (US); Jungmin KO, San Jacinto, CA (US); Tom CHOI, Sunnyvale, CA (US); Yi XU, San Jose, CA (US)

(21) Appl. No.: 18/666,216

(22) Filed: May 16, 2024

(51) Int. Cl. H01L 21/033; C23C 16/04; C23C 16/06; C23C 16/50; H01J 37/32; H01L 21/311

(52) U.S. Cl. CPC H01L 21/0332; C23C 16/042; C23C 16/06; C23C 16/50; H01J 37/32733; H01L 21/31144; H01J 37/32091; H01J 2237/3321; H01J 2237/334; H01J 2237/335

(57) ABSTRACT

Embodiments herein are generally directed to systems and methods for producing and depositing a hard mask on a film stack of a semiconductor memory device. A substrate processing system includes a film formation chamber, a plasma etching chamber, a transfer chamber configured to transport a substrate between the film formation chamber and the plasma etching chamber, and a controller. The controller is configured to cause the substrate processing system to deposit, using the film formation chamber, a doped hard mask having a metal material, a carbon-containing material, and a dopant material on a film stack disposed on a substrate, etch, using the plasma etching chamber, the doped hard mask and the film stack to produce trench features in the film stack, and deposit, using the film formation chamber, a bulk metal in the trench features and on the doped hard mask.

### BACKGROUND

### Field

Embodiments herein are generally directed to systems and methods for semiconductor manufacturing and, more particularly, to systems and methods for producing and depositing a hard mask on a film stack of a semiconductor memory device.

### Description of the Related Art

Hard masks are used in chemical vapor deposition (CVD) etching processes of semiconductor manufacturing to transfer a pattern to a desired substrate. Hard masks are used in, for example, a low-k etch step of semiconductor manufacturing where a low dielectric constant (low-k) material is etched. In this process, a hard mask is often used to protect certain areas of the low-k material from being etched away. The hard mask provides etching selectivity to the low-k materials during the dry etching process.

The grain size of the hard mask material can influence the uniformity and smoothness of the etched features. Smaller grain sizes can lead to smoother etched surfaces, which is beneficial for high-resolution patterning. In contrast, larger grain sizes might result in rougher etched surfaces, which can cause issues in subsequent process steps. Smaller grains can lead to a more uniform distribution of material, which can result in smoother etched surfaces. This is particularly beneficial for high-resolution patterning where the precision of the etched features is critical. Smaller grains also have fewer defects that can cause roughness. Larger grains might result in rougher etched surfaces, which can cause issues in subsequent process steps. Additionally, larger grain sizes lead to greater line roughness of the etched materials, which impacts the performance of the device being manufactured, e.g., increasing resistance or limiting effective resolution.

Accordingly, there is a need for improved systems and methods to produce hard masks in low-k etching processes to reduce grain size and improve etch selectivity.

### SUMMARY

Embodiments herein are generally directed to systems and methods for semiconductor manufacturing and, more particularly, to systems and methods for producing and depositing a hard mask on a film stack of a semiconductor memory device.

In an embodiment, a substrate processing system is provided. The substrate processing system includes a film formation chamber, a plasma etching chamber, a transfer chamber configured to transport a substrate between the film formation chamber and the plasma etching chamber, and a controller. The controller is configured to cause the substrate processing system to deposit, using the film formation chamber, a doped hard mask having a metal material, a carbon-containing material, and a dopant material on a film stack disposed on a substrate, etch, using the plasma etching chamber, the doped hard mask and the film stack to produce trench features in the film stack, and deposit, using the film formation chamber, a bulk metal in the trench features and on the doped hard mask.

In another embodiment, a processing chamber is provided. The processing chamber includes a substrate support assembly disposed within a processing volume of the processing chamber, a gas delivery system fluidly coupled to the processing chamber and including a metal precursor gas source, a carbon-containing gas source, and dopant gas source, and a controller. The controller is configured to cause the processing chamber to depositing, using the gas delivery system, a doped hard mask having a dopant material on a film stack of a substrate disposed on the substrate support assembly, and after etching the film stack to produce trench features in an etching chamber, depositing a bulk metal in the trench features.

In yet another embodiment, a method of processing a substrate is provided. The method includes depositing a doped hard mask having a dopant material on a film stack disposed on a substrate, etching the doped hard mask and the film stack to produce trench features in the film stack, depositing a bulk metal in the trench features and on the doped hard mask, and removing the doped hard mask from the film stack.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIG. 1 illustrates a substrate processing system, according to certain embodiments.

FIG. 2 is a cross-sectional view of a processing chamber of substrate processing system of FIG. 1, according to certain embodiments.

FIG. 3 illustrates a cross-sectional view of a memory device, according to certain embodiments.

FIG. 4 illustrates a method of processing a substrate, according to certain embodiments.

FIGS. 5A, 5B, 5C, and 5D illustrate a substrate undergoing the method of FIG. 4, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to systems and methods for semiconductor manufacturing and, more particularly, to systems and methods for producing and depositing a hard mask on a film stack of a semiconductor memory device.

Hard masks are used in Chemical Vapor Deposition (CVD) etching processes for pattern transfer to the desired substrate. Hard masks are used in, for example, a low-k etch step where a low dielectric constant (low-k) material is etched. Low-k materials are used in the interconnect layers of integrated circuits to reduce capacitive coupling and improve device performance. In this process, a hard mask is often used to protect certain areas of the low-k material from being etched away. The hard mask material is deposited and patterned using a standard photoresist process. After the hard mask is patterned, the underlying low-k material can be etched through the hard mask. The hard mask provides better etching selectivity to the low-k materials during the dry etching process. After the etching process, the hard mask is typically removed with a further etching process. This ensures that the hard mask does not interfere with subsequent process steps.

The grain size of the hard mask material can influence the uniformity and smoothness of the etched features. Smaller grain sizes can lead to smoother etched surfaces, which is beneficial for high-resolution patterning. However, larger grain sizes might result in rougher etched surfaces, which can cause issues in subsequent process steps. Smaller grains can lead to a more uniform distribution of material, which can result in smoother etched surfaces. This is particularly beneficial for high-resolution patterning where the precision of the etched features is critical. Smaller grains also have fewer defects that can cause roughness. Larger grains might result in rougher etched surfaces, which can cause issues in subsequent process steps.

Further, a high ratio of the etch rate of the material being etched to the etch rate of the mask material, that is etch selectivity, is desirable as it ensures that the mask material is not significantly etched away during the etching of the underlying material, thereby maintaining the integrity of the patterned features.

The present disclosure provides for systems and methods to improve the etch selectivity and reduce grain size of hard masks for use in low-k etch processes. The present disclosure provides for a hard mask including tungsten carbide to be doped with a dopant at a dopant concentration. The dopant may include suitable dopant materials, such as boron, silicon, and nitrogen. The addition of the dopant to the tungsten carbide hard mask significantly reduces the grain size of the hard masks without affecting throughput of the etching processes, resulting in significant improvements in line roughness.

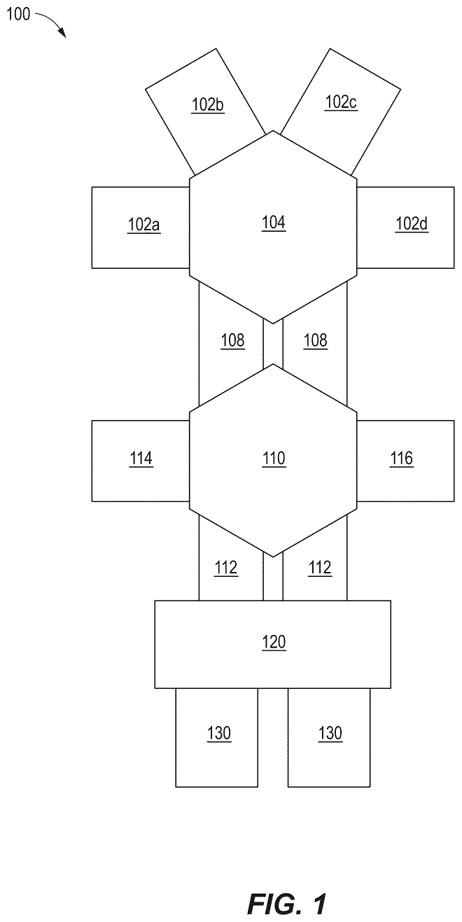

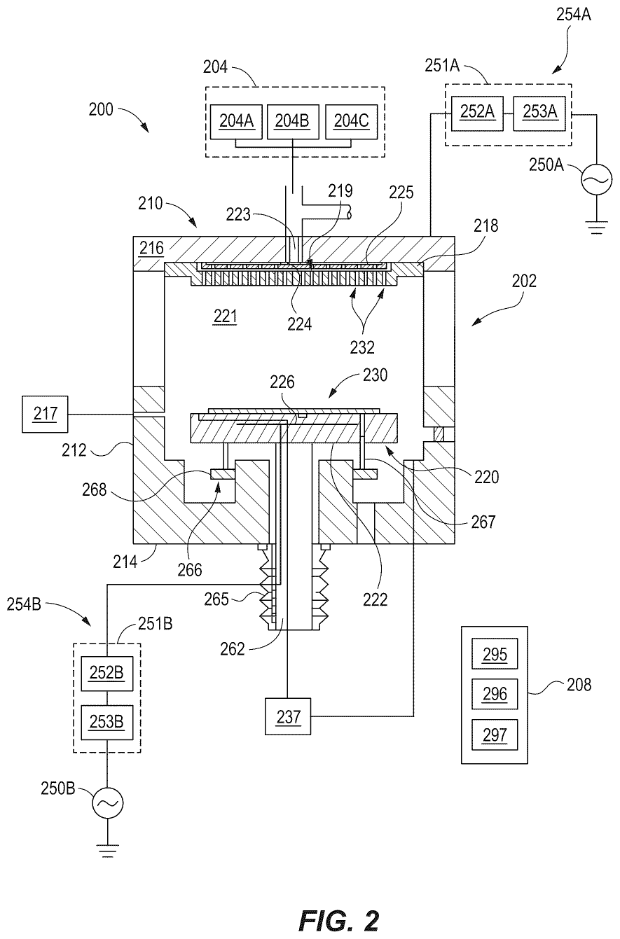

FIG. 1 illustrates a substrate processing system 100, according to certain embodiments. The substrate processing system 100 has an internal volume which is isolated from ambient environment. As shown in FIG. 1, a plurality of processing chambers 102a, 102b, 102c, 102d are coupled to a first transfer chamber 104. The processing chambers 102a-102d may be used to perform any substrate related processes, such as annealing, chemical vapor deposition, physical vapor deposition, epitaxial process, etching process, thermal oxidation or thermal nitridation process, degassing, etc. In one example, the processing chamber 102a may be a film formation chamber. In some examples, the processing chamber 102a may be plasma-enhanced chemical vapor deposition (PECVD) chamber such as the processing chamber 202 described in FIG. 2.

The processing chamber 102b may be a rapid thermal processing chamber (RTP). The processing chamber 102c may be a plasma etching chamber or a plasma cleaning chamber. The processing chamber 102d may be a degassing chamber. The first transfer chamber 104 is also coupled to at least one transition station, for example a pair of pass-through stations 106, 108. The pass-through stations 106, 108 maintain vacuum or inert environment conditions while allowing substrates to be transferred between the first transfer chamber 104 and a second transfer chamber 110. The first transfer chamber 104 may have a robotic substrate handling mechanism for transferring substrates between the pass-through stations 106, 108 and any of the processing chambers 102a-102d. The processing chambers 102a-102d are shown configured in a certain order in FIG. 1, but the processing chambers 102a-102d may be configured in any desired order.

One end of the pass-through stations 106, 108 is coupled to the second transfer chamber 110. Therefore, the first transfer chamber 104 and the second transfer chamber 110 are separated and connected by the pass-through stations 106, 108. The second transfer chamber 110 is coupled to a first preclean chamber 114 and a second preclean chamber 116, each of which may be an oxide removal chamber that are adapted to remove oxides from a surface of a substrate.

In one example, the at least one transition station, for example one of the pass-through stations 106, 108, may be a plasma-cleaning chamber. Alternatively, a plasma-cleaning chamber may be coupled to one of the pass-through stations 106, 108 for removing contaminants from the surface of the substrate. Thus, the vacuum processing system 100 may have a plasma-cleaning chamber that is, or is connected to, one of the pass-through stations 106, 108. The plasma-cleaning chamber may be adapted for removing contaminants from the surface of the substrate. In one example, a plasma-cleaning chamber may be coupled to both of the pass-through stations 106 and 108.

The second transfer chamber 110 may also have a robotic substrate handling mechanism for transferring substrates between a set of load lock chambers 112 and the first preclean chamber 114 or the second preclean chamber 116. A factory interface 120 is connected to the second transfer chamber 110 by the load lock chambers 112. The factory interface 120 is coupled to one or more pods 130 on the opposite side of the load lock chambers 112. The pods 130 may be front opening unified pods (FOUP) that are accessible from a clean room.

While two transfer chambers are shown, it is contemplated that either of the transfer chambers may be omitted. In one example in which the second transfer chamber 110 is omitted, the first preclean chamber 114 and second preclean chamber 116 may be disposed within or coupled to the first transfer chamber 104 at the location currently shown as occupied by the pass-through stations 106 and 108. The first transfer chamber 104 may be coupled to one or more processing chambers capable of forming crystalline silicon or silicon germanium, such as an epitaxy chamber. Alternatively, the first transfer chamber 104 may be omitted and the second transfer chamber 110 may be configured to be coupled to one or more processing chambers capable of forming crystalline silicon or silicon germanium.

In operation, substrates are removed, one at a time, from the pods 130 and transferred to the vacuum processing system 100. Each substrate is initially moved through the factory interface 120 which is coupled to the pods 130 and placed in one of the load lock chambers 112. The robotic transport mechanism within the second transfer chamber 110 transports the substrates, one at a time, from the load lock chambers 112 to the first preclean chamber 114 or second preclean chamber 116 where a cleaning process, such as an oxide cleaning process, is performed to remove oxides from a surface of a substrate. Once the oxides have been removed from the substrate surface, the robotic transport mechanism disposed within the second transfer chamber 110 transfers the substrate from the first preclean chamber 114 or second preclean chamber 116 to the pass-through station 106. Then the robotic transport mechanism disposed within the first transfer chamber 104 transfers the substrate from the pass-through station 106 to one or more processing chambers 102a-102d. The one or more processing chambers 102a-102d may include an epitaxy process chamber where a layer formation process, such as an epitaxial deposition process, is performed.

Upon completion of processing in the one or more processing chambers 102a-102d, the robotic transport mechanism disposed within the first transfer chamber 104 transfers the substrate from either one of the processing chambers 102 to the pass-through station 108. The substrate is then removed from the pass-through station 108 by the robotic transport mechanism disposed within the second transfer chamber 110 and transferred to the other load lock chamber 112 through which the substrate is withdrawn from the vacuum processing system 100. The example substrate movement sequence described above is provided for illustration purposes only, and other substrate movement sequences are contemplated.

Since the processes are performed within the same vacuum processing system 100, vacuum is not broken as the substrate is transferred between chambers, which decreases the chance of contamination and improves the quality of the deposited epitaxial film. In some examples, a controller, e.g., the system controller 208 shown in FIG. 2, may be coupled to the vacuum processing system 100 for controlling the vacuum processing system 100 or components thereof. The controller may be used to schedule the movement of the substrates through the vacuum processing system 100 in accordance with a desired sequencing program, which may vary depending upon the application.

FIG. 2 illustrates a substrate processing system 200 configured to generate a capacitively-coupled plasma that may be used for deposition, including PECVD, according to certain embodiments. Although the substrate processing system 200 is shown to be configured to generate a capacitively coupled plasma, it is contemplated that the substrate processing system may be configured to generate an inductively-coupled plasma (not shown) or use a remote plasma source (not shown) to deliver a plasma to a substrate. The substrate processing system 200 includes a processing chamber 202, a gas delivery system 204 fluidly coupled to the processing chamber 202, and a system controller 208. The processing chamber 202 includes a chamber lid assembly 210, one or more sidewalls 212, and a chamber base 214, which collectively define a processing volume 221. The processing volume 221 is fluidly coupled to an exhaust 217, such as one or more vacuum pumps, used to maintain the processing volume 221 at sub-atmospheric conditions and to evacuate processing gases and processing by-products therefrom.

The chamber lid assembly 210 includes a lid plate 216 and a showerhead 218 coupled to the lid plate 216 to define a gas distribution volume 219. The showerhead 218 faces a substrate support assembly 220 disposed in the processing volume 221. The substrate support assembly 220 is configured to move a substrate support 222 between a raised substrate processing position (as shown) and a lowered substrate transfer position (not shown).

The gas delivery system 204, which includes a metal precursor gas source 204A, a carbon-containing gas source 204B, and a dopant gas source 204C, is fluidly coupled to the processing chamber 202 through at least one gas inlet 223 that is disposed through the lid plate 216, one or more sidewalls 212, or both. The metal precursor gas source 204A may deliver metal precursor gases, including tungsten fluoride (WF₆), tungsten carbonyl (W(CO)₆), bis-(tert-butylimido)-bis (dimethylamido) tungsten, or a combination thereof. The carbon-containing gas source 204B may deliver carbon-containing gases, such as hydrocarbon precursors. For example, the carbon-containing gas source 204B may flow propene, or acetylene. The dopant gas source 204C may deliver dopant gases, such as diborane, trimethylborane, silane, tetrafluorosilane, trimethylsilane, tetramethylsilane, ammonia, or a combination thereof. Optionally, the dopant gas source 204C may flow two or more dopant gases, such as a boron-containing gas and a nitrogen-containing gas, to deliver two dopant materials for deposition.

Processing or cleaning gases delivered by the gas delivery system 204 may flow through the at least one gas inlet 223 in the lid plate 216 and a baffle 224 into the gas distribution volume 219 and are distributed into the processing volume 221 through a plurality of openings 232 in the showerhead 218. The chamber lid assembly 210 further includes a perforated diffusion plate 225 disposed between the at least one gas inlet 223 in the lid plate 216 and the showerhead 218. The gases flowed into the gas distribution volume 219 are first diffused by the perforated diffusion plate 225 to provide a more uniform or desired distribution of gas flow into the processing volume 221. Cleaning gases can also be delivered through the at least one gas inlet 223 in the one or more sidewalls 212 and into the processing volume 221. Processing gases and processing by-products are evacuated from the processing volume 221 through openings in the one or more sidewalls 212.

A purge gas source 237 in fluid communication with the processing volume 221 is used to flow a chemically inert purge gas, such as argon (Ar) or helium (He), into a region disposed beneath the substrate support 222, e.g., through the opening in the chamber base 214 surrounding a movable support shaft 262 supporting the substrate support 222. The purge gas may be used to create a region of positive pressure below the substrate support 222 when compared to the pressure in the processing volume 221 during substrate processing. Typically, purge gas introduced through the chamber base 214 flows up and around the edges of the substrate support 222 to be evacuated from the processing volume 221 through openings in the one or more sidewalls 212.

The substrate support assembly 220 includes the movable support shaft 262 that may be surrounded by a bellows 265. The substrate support assembly 220 includes a lift pin assembly 266 comprising a plurality of lift pins 267 coupled to a lift pin hoop 268. The plurality of lift pins 267 are movably disposed in openings formed through the substrate support 222. When the substrate support 222 is disposed in a lowered substrate transfer position (not shown), the plurality of lift pins 267 extend above a substrate receiving surface of the substrate support 222 to lift a substrate 230 and provide access to a backside surface of the substrate 230. When the substrate support 222 is in a raised or processing position, the plurality of lift pins 267 recede beneath the substrate receiving surface of the substrate support 222 to allow the substrate 230 to rest thereon. The plurality of lift pins 267 may lift the substrate 230 during processing, such as during a remote plasma source cleaning process or an RF capacitively coupled cleaning process, such that cleaning gases and cleaning plasma may flow on opposing sides of the substrate 230, e.g., the front side and the backside of the substrate 230.

As shown, the substrate processing system 200 may be configured to form a capacitively coupled plasma (CCP), including an upper electrode, e.g., lid plate 216, disposed adjacent the processing volume 221 facing a lower electrode, e.g., substrate support assembly 220, disposed in the processing volume 221 opposite the upper electrode. A first plasma generator assembly 254A includes a first RF generator 250A and a first RF generator assembly 251A, and is electrically coupled to the upper electrode to deliver an RF signal configured to ignite and maintain a plasma. The first RF generator 250A includes a first RF matching circuit 253A and a first filter assembly 252A disposed within the first RF generator assembly 251A. Alternatively, the showerhead 218 may be electrically coupled to the first RF generator 250A to ignite and maintain a plasma of processing gases flowed into the processing volume 221 through capacitive coupling therewith.

The lower electrode, e.g., the substrate support assembly 220, is coupled to a second RF generator assembly 254B. As shown in FIG. 2, one or more components of the substrate support assembly 220, such as a substrate electrode 226 embedded in the substrate support assembly 220, is electrically coupled to the second RF generator assembly 254B. The second RF generator assembly 254B includes a second RF generator 250B that is coupled to a second RF matching circuit 253B and a second filter assembly 252B disposed within a second RF generator assembly 251B.

The second RF generator assembly 254B, which includes the second RF generator 250B and the second RF generator assembly 251B, is generally configured to deliver a desired amount of pulsed RF bias at a desired pulsing frequency to the substrate electrode 226 of the substrate support assembly 220 based on control signals provided from the system controller 208. During processing, the second RF generator assembly 254B is configured to deliver pulsed RF power, e.g., a pulsed RF signal, to the substrate electrode 226 disposed proximate to the substrate support 222, and within the substrate support assembly 220. The pulsed RF power delivered to the substrate electrode 226 is configured to ignite and maintain the processing plasma using the processing gases disposed in the processing volume 221 and fields generated by the pulsed RF power delivered to the substrate electrode 226 by the second RF generator 250B.

The system controller 208 generally includes a central processing unit (CPU) 295, memory 296, and support circuits 297. The CPU 295 may be one of any form of a general purpose processor that can be used in an industrial setting. The memory 296, or non-transitory computer-readable medium, is accessible by the CPU 295 and may be one or more of memory such as random access memory (RAM), read only memory (ROM), floppy disk, hard disk, or any other form of digital storage, local or remote. The support circuits 297 are coupled to the CPU 295 and may comprise cache, clock circuits, input/output subsystems, power supplies, and the like. The various methods disclosed herein may generally be implemented under the control of the CPU 295 by the CPU 295 executing computer instruction code stored in the memory 296 (or in memory of a particular processing chamber) as, for example, a software routine. When the computer instruction code is executed by the CPU 295, the CPU 295 controls the processing chambers to perform processes in accordance with the various methods.

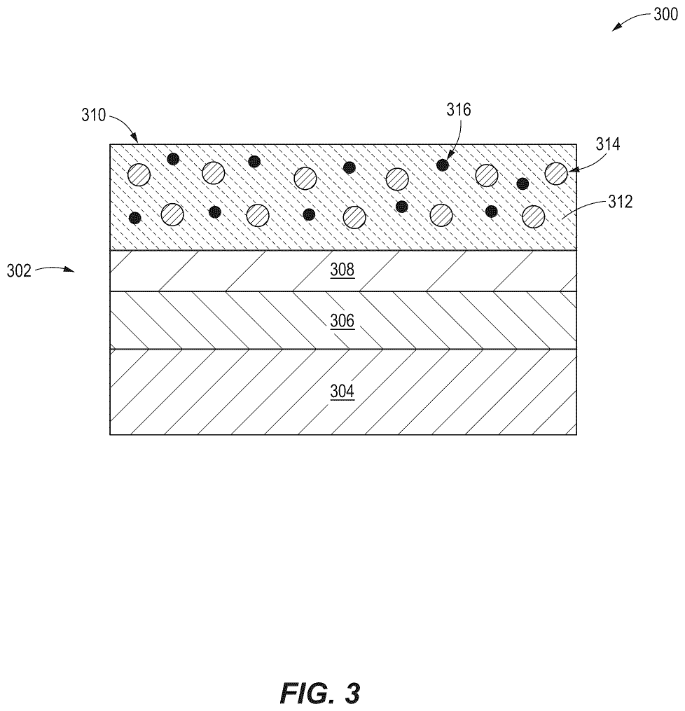

FIG. 3 illustrates a cross-sectional view of a memory device 300, according to certain embodiments. In particular, the memory device 300 includes a film stack 302 that may include an interdielectric layer 304, a passivation layer 306, and an adhesion layer 308. The interdielectric layer 304 may include a layer or layers of dielectric materials, such as silicon dioxide (SiO₂), borophosphosilicate glass (BPSG), silicon nitride (Si₃N₄), low-k dielectrics like carbon-doped oxides, thin film metals, or a combination thereof. The passivation layer 306 may be a layer of a metal oxide, such as tungsten oxide, that may be formed by atomic layer deposition and intended to stabilize the film stack 302. A doped hard mask 310 is disposed on the film stack 302. The adhesion layer 308 may be deposited using a plasma-enhanced atomic layer deposition (PEALD) process and may include transition metal nitride, such as tungsten nitride, and is used to improve the adhesion of the doped hard mask 310 to the film stack 302. As shown in FIG. 3, the doped hard mask 310 is disposed on the adhesive layer 308, however, the doped hard mask 310 may be disposed in any layer of the film stack 302, including directly on the interdielectric layer 304.

The doped hard mask 310 includes a metal material 312, a carbon-containing material 314, and a dopant material 316. The metal material 312 may include any suitable hard mask metals, including tungsten (W) and titanium (Ti). The carbon-containing material 314 may include carbon, such as amorphous carbon, that is bonded to the metal material 312, e.g., to form tungsten carbide. The dopant material 316 may include any suitable dopant material, such as boron (B), silicon (Si), nitrogen (N), or a combination thereof. For example, the dopant material may include only boron or only silicon to produce a doped hard mask 310 having a WCB or WCSi composition. Alternatively, the dopant material 316 may include two or more dopant materials, e.g., boron and nitrogen or silicon and nitrogen, to produce a doped hard mask 310 having a WBCN or a WSiCN composition.

The doped hard mask 310 may include a weight percentage (wt %) of the metal material 312 from about 1 wt % to about 90 wt % of the total composition of the doped hard mask 310, such as about 25 wt % to about 50 wt %. The concentration of the metal material 312 is chosen such that the doped hard mask 310 may effectively prevent degradation or etching of the layers, e.g., the adhesive layer 308, of the film stack 302 underneath the doped hard mask 310. Similarly, the doped hard mask 310 may include a weight percentage of carbon-containing material 314 of about 1 wt % to about 90 wt % of the total composition of the doped hard mask 310, such as about 15 wt % to about 65 wt %. Similarly, the weight percentage of the carbon-containing material 314 is chosen such that the defect control of the doped hard mask 310 is maintained when the carbon-containing material 314 is bonded to the metal material 312.

The doped hard mask 310 may also include a weight percentage of the dopant material 316 from about 0.05 wt % to about 15 wt % of the total composition of the doped hard mask 310, such as about 0.5 wt % to about 10 wt %, such as about 1 wt % to about 5 wt %. The addition of the dopant material 316 allows for the doped hard mask 310, e.g., a tungsten carbide hard mask, to have improved etch selectivity and reduced grain size, which then improves line roughness of the doped hard mask 310 and, subsequently, of the etched features of the memory device 300 below the doped hard mask 310.

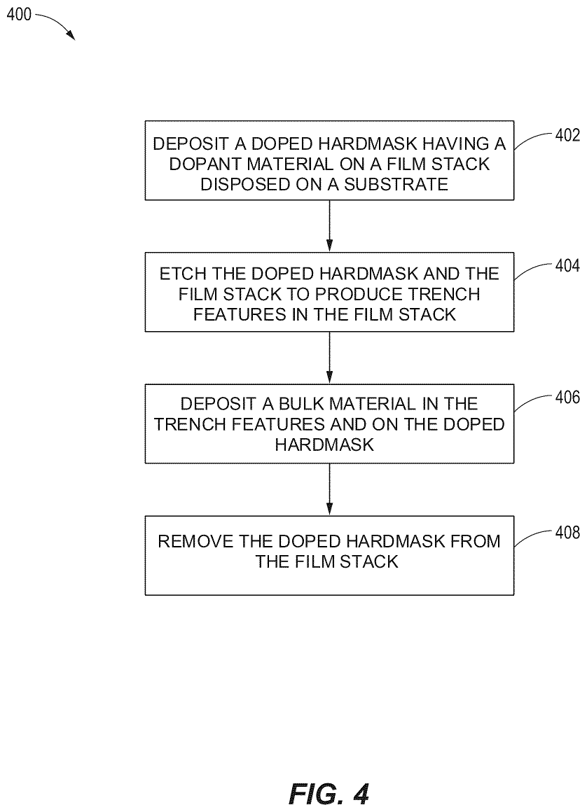

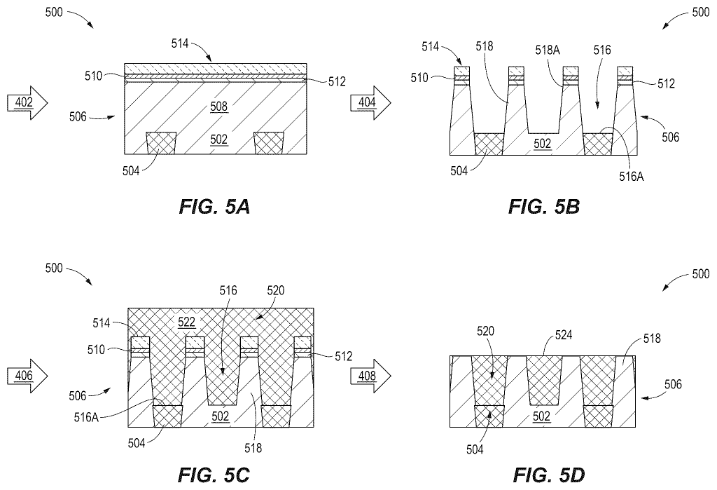

FIG. 4 illustrates a method 400 of processing a substrate, according to certain embodiments, which may be performed by the system controller 208 of the processing chamber 202 of FIG. 2. FIGS. 5A, 5B, 5C, and 5D illustrate a memory device 500 undergoing the method 400 of FIG. 4 in the processing chamber 202 of FIG. 2, according to certain embodiments.

In operation 402 of the method 400, a doped hard mask 514 having a doped material, similar to the dopant material 316 of FIG. 3, is deposited on a film stack 506 disposed on a substrate 502, as shown in FIG. 5A. The substrate 502 may include one or more via 504. The one or more via 504 may be filled with a via metal, such as tungsten, copper, or molybdenum. The film stack 506 may include a interlayer dielectric 508 having a adhesion layer 510 and a cap layer 512 disposed between the film stack 506 and the doped hard mask 514. The interlayer dielectric 508 may include any suitable dielectric materials, such as silicon oxide (SiO₂ or SiOₓ), and may include multiple layers of different dielectric materials. The adhesion layer 510 may include a nitride layer, e.g., a tungsten nitride or a titanium nitride layer, which may be deposited using a plasma-enhanced atomic layer deposition (PEALD) process. The cap layer 512 may include suitable cap layer materials, such as silicon oxide (SiOₓ) and is configured to passivate or protect the film stack 506 from intermixing and diffusion with materials of the doped hard mask 514.

The doped hard mask 514 may be deposited onto the film stack 506 by any suitable method, such as plasma enhanced chemical vapor deposition (PECVD), in the processing chamber 202. For example, the metal precursor gas source 204A, the carbon-containing gas source 204B, and the dopant gas source 204C may co-flow process gases to deposit the doped hard mask 514. The metal precursor gas source 204A may flow a metal precursor, such as tungsten-containing precursor. The metal precursor may be, for example, tungsten fluoride (WF₆), tungsten carbonyl (W(CO)₆), bis-(tert-butylimido)-bis (dimethylamido) tungsten, or a combination thereof. The metal precursor may be flowed at a metal flow rate of about 2.5 sccm to about 7500 sccm, such as about 5 sccm to about 5000 sccm. The carbon-containing gas source 204B may flow a carbon-containing precursor, such as hydrocarbon precursors. For example, the carbon-containing gas source 204B may flow propene or acetylene. The carbon-containing gas source 204B may flow the carbon-containing precursor at a carbon flow rate of about 0.5 sccm to about 5000 sccm, such as about 2 sccm to about 3000 sccm. The dopant gas source 204C may flow a dopant gas, such as gases including boron (B), silicon (Si), or nitrogen (N), to deposit a dopant material including boron, silicon, nitrogen, or a combination thereof. For example, the dopant gas source 204C may flow diborane, trimethylborane, silane, tetrafluorosilane, trimethylsilane, tetramethylsilane, ammonia, or a combination thereof. The dopant gas source 204C may flow the dopant gas at a dopant flow rate of about 1 sccm to about 5000 sccm, such as about 2 sccm to about 3000 sccm. Inert or carrier gases may be co-flown with the metal precursor, carbon-containing precursor, and dopant gases, such as argon (Ar) or helium (He), at carrier gas flow rates of about 0.1 to about 20 slm to facilitate deposition onto the memory device 500, e.g. by a plasma. Alternatively, the doped hard mask 514 may be deposited using thermal CVD, where the process gases delivered by the metal precursor gas source 204A, the carbon-containing gas source 204B, and the dopant gas source 204C are co-flown without striking a plasma.

The deposited doped hard mask 514 may have a weight percentage (wt %) of a metal material, e.g., tungsten, from about 1 wt % to about 90 wt % of the total composition of the doped hard mask 310, such as about 25 wt % to about 50 wt %. The concentration of the metal material is chosen such that the doped hard mask 514 may effectively prevent degradation or etching of the layers, e.g., the interlayer dielectric 508, of the film stack 506 underneath the doped hard mask 514. Similarly, the doped hard mask 514 may include a weight percentage of a carbon material of about 1 wt % to about 90 wt % of the total composition of the doped hard mask 514, such as about 15 wt % to about 65 wt %. Similarly, the weight percentage of the carbon material is chosen such that the defect control of the doped hard mask 514 is maintained when the carbon material is bonded to the metal material.

The doped hard mask 514 may also include a weight percentage of the dopant material from about 0.05 wt % to about 15 wt % of the total composition of the doped hard mask 514, such as about 0.5 wt % to about 10 wt %, such as about 1 wt % to about 5% wt %. In examples where the metal material is tungsten, the addition of the dopant material produces a WBC or WSiC composition in the doped hard mask 514. The addition of the dopant material allows for the doped hard mask 514, e.g., a WBC or WSiC hard mask, to have improved etch selectivity and reduced grain size compared to a WC hard mask, which then improves line roughness of the doped hard mask 514 and, subsequently, of the etched features of the memory device 500 below the doped hard mask 514.

In operation 404, the doped hard mask 514 may be etched or patterned, followed by etching of the film stack 506, as shown in FIG. 5B, using low-k etching processes. For example, the doped hard mask 514 and the film stack 506 may be etched by sequential reactive ion etching (RIE) processes. In this process, plasma is traditionally formed using a radio-frequency (RF) source and ions inside the plasma accelerate toward a substrate surface under the influence of a biasing voltage applied to a metal plate known as a cathode. The cathode can be coupled to the plasma using capacitive coupling through a dielectric layer. This sequential etching processes produce trench features 516 between film stack structures 518. The trench features 516 may have a bottom surface bottom surface 516A at the one or more via 504 of the substrate 502. The film stack structures 518 each have portions of the patterned doped hard mask 514, the cap layer 512, and the adhesion layer 510 on a top surface 518A of the film stack structures 518.

In operation 406, a bulk metal 520 may be deposited in the trench features 516 and over the film stack structures 518, e.g., a overburden bulk metal 522, as shown in FIG. 5C. The bulk metal 520 may fill the trench features 516 and contact the one or more via 504 of the substrate 502. The bulk metal 520 may be any suitable metal material, such as tungsten, copper, or molybdenum. Although the bulk metal 520 is shown to be the same material as the material of the one or more via 504, it is contemplated that the bulk metal 520 may be a material differing from that used in the one or more via 504. Similarly, the material of the bulk metal 520 may be a single material or a plurality of materials. The bulk metal 520 and the overburden bulk metal 522 may be deposited using any suitable deposition method. For example, the bulk metal 520 and the overburden bulk metal 522 may be deposited by PECVD using the processing chamber 202.

In operation 408, the overburden bulk metal 522 and the doped hard mask 514 are removed from the film stack structures 518 to produce a planar surface 524 at the top surface 518A of the film stack structures 518, as shown in FIG. 5D. The overburden bulk metal 522 and the doped hard mask 514 may be removed using the chemical mechanical polishing (CMP) in a CMP system (not shown).

The present disclosure provides for systems and methods to improve the etch selectivity and reduce grain size of hard masks for use in low-k etch processes. The present disclosure provides for a hard mask, including a metal material and carbon, to be doped with a dopant at a dopant concentration. The dopant may include suitable dopant materials, such as boron, silicon, and nitrogen. The addition of the dopant to the tungsten carbide hard mask significantly reduces the grain size of the hard masks without affecting throughput of the etching processes, resulting in significant improvements in line roughness.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A substrate processing system, comprising:
a film formation chamber;
a plasma etching chamber;
a transfer chamber configured to transport a substrate between the film formation chamber and the plasma etching chamber; and
a controller configured to cause the substrate processing system to:
deposit, using the film formation chamber, a doped hard mask having a metal material, a carbon-containing material, and a dopant material on a film stack disposed on a substrate;
etch, using the plasma etching chamber, the doped hard mask and the film stack to produce trench features in the film stack; and
deposit, using the film formation chamber, a bulk metal in the trench features and on the doped hard mask.

2. The substrate processing system of claim 1, wherein depositing the doped hard mask comprises:
flowing a metal precursor, a carbon-containing precursor, and a dopant gas into the film formation chamber having the substrate disposed therein.

3. The substrate processing system of claim 2, wherein the dopant material comprises boron, silicon, nitrogen, or a combination thereof.

4. The substrate processing system of claim 2, wherein the dopant gas comprises diborane, trimethylborane, silane, tetrafluorosilane, trimethylsilane, tetramethylsilane, ammonia, or a combination thereof.

5. The substrate processing system of claim 1, wherein the doped hard mask comprises between about 0.5% by weight and about 10% by weight of the dopant material.

6. The substrate processing system of claim 1, wherein the doped hard mask comprises between about 10% by weight and about 60% by weight of the metal material.

7. The substrate processing system of claim 1, wherein the metal material comprises tungsten carbide.

8. A processing chamber, comprising:
a substrate support assembly disposed within a processing volume of the processing chamber;
a gas delivery system fluidly coupled to the processing chamber and including a metal precursor gas source, a carbon-containing gas source, and dopant gas source; and
a controller coupled to the processing chamber and configured to cause the processing chamber to:
deposit, using the gas delivery system, a doped hard mask having a dopant material on a film stack of a substrate disposed on the substrate support assembly; and
after etching the film stack to produce trench features in an etching chamber, deposit a bulk metal in the trench features.

9. The processing chamber of claim 8, wherein the doped hard mask comprises tungsten carbide and the dopant material.

10. The processing chamber of claim 8, wherein depositing the doped hard mask comprises:
flowing a metal precursor, a carbon-containing gas, and a dopant gas into the processing volume having the substrate disposed therein.

11. The processing chamber of claim 10, wherein the dopant material of the doped hard mask includes boron, silicon, nitrogen, or a combination thereof.

12. The processing chamber of claim 10, wherein the metal precursor comprises tungsten fluoride (WF₆), tungsten carbonyl (W(CO)₆), bis-(tert-butylimido)-bis (dimethylamido) tungsten, or a combination thereof.

13. The processing chamber of claim 10, wherein the doped hard mask comprises about 0.5 wt % to about 10 wt % of the dopant material.

14. The processing chamber of claim 10, wherein the dopant gas comprises diborane, trimethylborane, silane, tetrafluorosilane, trimethylsilane, tetramethylsilane, ammonia, or a combination thereof.

15. A method of processing a substrate, comprising:
depositing a doped hard mask having a dopant material on a film stack disposed on a substrate;
etching the doped hard mask and the film stack to produce trench features in the film stack;
depositing a bulk metal in the trench features and on the doped hard mask; and
removing the doped hard mask from the film stack.

16. The method of claim 15, wherein the doped hard mask comprises tungsten carbide and a dopant material.

17. The method of claim 15, wherein depositing the doped hard mask comprises:
flowing a metal precursor, a carbon-containing precursor, and a dopant gas into a processing chamber having the substrate disposed therein.

18. The method of claim 17, wherein the dopant material comprises boron, silicon, nitrogen, or a combination thereof.

19. The method of claim 17, wherein the dopant gas comprises diborane, trimethylborane, silane, tetrafluorosilane, trimethylsilane, tetramethylsilane, ammonia, or a combination thereof.

20. The method of claim 15, wherein the doped hard mask comprises between about 0.5 wt % and about 10 wt % of the dopant material.
